(19) United States
(12) Patent Application Publication
(10) Pub. No.: US 2010/0326506 A1
(43) Pub. Date: Dec. 30, 2010

(54) Photovoltaic Cells Comprising Group IV-VI Semiconductor Core-Shell Nanocrystals

(75) Inventors: Efrat Lifshitz, Haifa (IL); Volker Hilarius, Darmstadt (DE)

Correspondence Address: BLANK ROME LLP, ONE LOGAN SQUARE, PHILADELPHIA, PA, 19103, US

(73) Assignee: Merck Patent GMBH, Darnstadt (DE)

(21) Appl. No.: 12/808,024

(22) PCT Filed: Dec. 14, 2008
(86) PCT No.: PCT/IL2008/001614

§ 371 Date: Sep. 13, 2010

Related U.S. Application Data
(60) Provisional application No. 61/013,538, filed on Dec. 13, 2007.

(51) Int. Cl. H01L 31/0352

(52) U.S. Cl. 136/255; 257/E31.033; 977/813; 977/774; 977/948

(57) ABSTRACT

The present invention relates to photovoltaic cells comprising group IV-VI semiconductor nanocrystals as photoactive components. In particular, these nanocrystals are of core-shell or core-alloyed shell configuration, each comprising a core of a first group IV-VI semiconductor material having a selected band gap energy, and either a core-overcoating shell consisting of a second group IV-VI semiconductor material or a core-overcoating alloyed shell consisting of an alloy of said first group IV-VI semiconductor material and a second group IV-VI semiconductor material, respectively.

### FIELD OF THE INVENTION

The present invention relates to photovoltaic cells comprising group IV-VI core-shell or core-alloyed shell semiconductor nanocrystals as photoactive components, wherein said nanocrystals may be in the form of spheroids or rods.

### BACKGROUND OF THE INVENTION

Photovoltaic cells (PVCs) use semiconductors to convert light energy into electrical current, regarded as one of the key technologies towards a sustainable energy supply. The so-called “first-generation” of PVCs is based on a single p-n junction of a crystalline-Si, exhibiting a power conversion efficiency (η) of 15-20%, thereby approaching the theoretical energy conversion efficiency limit of 31% (Shockley and Queisser, 1961).

The poor absorbing properties of the crystalline Si and its production cost led to the development of the second-generation of PVCs based on thin film technologies, using amorphous-, poly-crystalline- or micro-crystalline-Si (Fujiwara and Kondo, 2007), cadmiun telluride (CdTe) (Gur et al., 2005; Zhong et al., 2007), copper (gallium) indium selenide/sulphide (CIS) (Durisch et al., 2006) or GaAs based multi-junctions (Hannappel et al., 2007). Preparation of uniform thin films over large area substrates using evaporation techniques, or roll-to-roll process, is a challenging task and quite costly. Thus, the second-generation alternatives either do not overcome the theoretical limit of η=31%, neither substantially reduce the manufacturing costs in terms of $/kWatt-hour of electrical output. The third-generation of PVCs aims to achieve similar conversion efficiencies, using high quality light absorbing materials that enable the reduction of the $/kWatt-hour cost. This third-generation of PVCs includes the dye sensitizer PVCs (Bach et al., 1998; Gratzel, 2007; Plass et al., 2002), polymer-based PVCs (Brabec et al., 2001) and semiconductor nanocrystal PVCs (Nozik, 2002; Huynh et al., 2002). The dye- and polymer-based PVCs suffer from poor photo-stability. Thus, the most promising PVCs should rely on the implementation of semiconductor nanocrystals into cells that are solely based on inorganic components (Law et al., 2008, Koleilat et al., 2008).

US 20080142075 discloses a photovoltaic device, comprising a first and a second electrodes, at least one of which is a transparent electrode that is substantially transparent to all or part of the solar spectrum, and a photoactive layer disposed between said first and second electrodes, where said photoactive layer comprises a first sublayer comprising first photoactive nanoparticles having a first band gap and a second sublayer comprising second photoactive nanoparticles having a second bandgap which is smaller than said first bandgap, where said first sublayer is disposed closer to said transparent electrode than said second sublayer.

US 20080230120 discloses a photovoltaic device, comprising a first photoactive layer comprised of a semiconductor material exhibiting absorption of radiation substantially in a visible region of the solar spectrum; a second photoactive layer comprised of nanostructured material exhibiting absorption of radiation substantially in an IR region of the solar spectrum; and a recombination layer, disposed between the first and second layers, and configured to promote charge transport between the first and second layers. This patent publication further discloses a photovoltaic device, comprising a first photoactive layer comprised of a semiconductor material exhibiting absorption of radiation substantially in a visible region of the solar spectrum; a top photoactive layer comprised of nanostructured material exhibiting absorption of radiation substantially in an UV region of the solar spectrum; a recombination layer, disposed between the first and top layers, and configured to promote charge transport between the first and top layers; a bottom photoactive layer comprised of nanostructured material exhibiting absorption of radiation substantially in an IR region of the solar spectrum; and a second recombination layer, disposed between the first and bottom layers, and configured to promote charge transport between the first and bottom layers.

WO 2008/054845 discloses a photovoltaic device comprising: a first electrode and a second electrode, at least one of which is transparent to solar radiation; and a photoactive layer between said first and said second electrodes that is in electron conducting communication with said first electrode and in hole conducting communication with said second electrode, wherein said photoactive layer comprises a photoactive nanostructure comprising a carbon nanotube (CNT) and a photosensitive nanoparticle.

US 2008/0216894A1 discloses deposition of sublayers of semiconductor nanocrystals with various sizes, mounted outside the photoactive layer in PVCs, permitting light collection within the visible regime, improving the power quantum efficiency. In particular, it discloses (i) an organic photovoltaic device comprising at least one quantum dot layer, wherein incident radiation upon the quantum dot layer is red-shifted to form red-shifted radiation, and at least one active layer which absorbs red-shifted radiation; (ii) a device comprising at least one organic photovoltaic active layer, at least one anode, at least one cathode, and optionally, at least one additional layer, wherein the device further comprises quantum dots which are not in the active layer; and (iii) an organic photovoltaic device comprising at least one nanostructured layer, wherein incident radiation upon the quantum dot layer is red-shifted to form red-shifted radiation, and at least one organic active layer which absorbs red-shifted radiation.

WO 2006/110919 and its corresponding US Publication No. 20070099359 disclose a PVC for converting light into charge carriers comprising: an anode and a cathode wherein at least one of said anode and cathode is transparent; a layer of semiconductor nanocrystals disposed on one of said anode and cathode, the layer of semiconductor nanocrystals capable of yielding carrier multiplication upon exposure to light of a sufficient energy level whereby greater than one electron-hole pair is generated per single absorbed photon from said light; and a current collection element wherein said current collection element is electrically connected to said anode or cathode, so as to remove charge carriers from the cell.

WO 2006/027778 and its corresponding US Publication No. 2008/0296534, herein incorporated by reference in their entirety as if fully described herein, disclose a core-alloyed shell semiconductor nanocrystal comprising: (i) a core of a semiconductor material having a selected band gap energy; (ii) a core-overcoating shell consisting of one or more layers comprised of an alloy of the said semiconductor of (i) and a second semiconductor; (iii) and an outer organic ligand layer, provided that the core semiconductor material is not HgTe. These publications further disclose a single-injection process for the synthesis of said core-alloyed shell semiconductor nanocrystal, comprising the simultaneous injection of stoichiometric amounts of the core and shell semiconductor materials or precursors thereof into a mother solution comprised of the organic ligands or in which mother solution the organic ligands are dissolved, at elevated temperatures, under inert conditions, whereby a fast nucleation of the core superconductor material occurs, followed by a deposition of the semiconductor shell material with a gradual composition.

WO 2006/035425 and its corresponding U.S. application Ser. No. 11/663,454, herein incorporated by reference in their entirety as if fully described herein, disclose a method for producing semiconductor nanoparticles comprising: (i) dissolving a semiconductor compound or mixture of semiconductor compounds in a solution; (ii) generating spray droplets of the resulting solution of semiconductor compound(s); (iii) vaporizing the solvent of said spray droplets, consequently producing a stream of unsupported semiconductor nanoparticles; and (iv) collecting said unsupported semiconductor nanoparticles on a support, preferably on a solid support.

### SUMMARY OF THE INVENTION

The present invention relates to a photovoltaic cell comprising group IV-VI semiconductor nanocrystals as photoactive components, wherein said nanocrystals are either:
(i) core-shell semiconductor nanocrystals each comprising a core of a first group IV-VI semiconductor material having a selected band gap energy and a core-overcoating shell consisting of a second group IV-VI semiconductor material; or
(ii) core-alloyed shell semiconductor nanocrystals each comprising a core of a first group IV-VI semiconductor material having a selected band gap energy and a core-overcoating alloyed shell consisting of an alloy of said first group IV-VI semiconductor material and a second group IV-VI semiconductor material.

The photovoltaic cells of the present invention may be constructed in any of the various configurations known in the art, i.e., the group IV-VI semiconductor nanocrystals as the photoactive components may be packed in any suitable configuration, enhancing either the photo-current or the photo-voltage and thus, the conversion efficiency. Furthermore, the group IV-VI semiconductor nanocrystals may be packed between a pair of Bragg reflectors, creating a photonic structure acting as a fluorescent collector.

Thus, the present invention further provides a photovoltaic device comprising a photovoltaic cell and a photonic structure that acts as a fluorescence collector, harvesting a wide spectral range of solar radiation, comprising group IV-VI semiconductor nanocrystals as photoactive components, packed as a single layer between a pair of Bragg reflectors,

wherein said nanocrystals are either:
(i) core-shell semiconductor nanocrystals each comprising a core of a group IV-VI semiconductor material having a selected band gap energy and a core-overcoating shell consisting of a second group IV-VI semiconductor material; or
(ii) core-alloyed shell semiconductor nanocrystals each comprising a core of a group IV-VI semiconductor material having a selected band gap energy and a core-overcoating alloyed shell consisting of an alloy of said group IV-VI semiconductor material and a second group IV-VI semiconductor material,

said nanocrystals emit photons at their band-edge energy, and said photons are internally reflected within a photonic cavity and then emitted from said photonic cavity with an enhanced intensity tuned to the absorption edge of a photoactive material being a component of said photovoltaic cell.

### BRIEF DESCRIPTION OF THE FIGURES

FIGS. 1A-1G show schematic drawings of core-shell nanocrystal dot (NQD) and nanorod (NR), representative transmission electron microscope images of certain core-shell NQDs and NRs, and the plausible electron-hole wave function radial distribution of a core-shell NQD and NR. In particular, schematic drawings of core-shell NQD and NR are shown in FIGS. 1A-1B, respectively, when an alloy layer is optionally exist between the core and the shell as demonstrated by the shaded area in A1; representative transmission electron microscope images of core-shell NQDs having core diameter of 3.9 nm and shell thickness of 0.55 nm, core-shell NQDs having core diameter of 1.8 nm and shell thickness of 1.6 nm, and core-shell NRs with length of ˜50 nm and width of ˜3 nm are shown in FIGS. 1C-1E, respectively; and the plausible electron-hole wave function radial distribution of a core-shell NQD and a core-shell NR are shown in FIGS. 1F-1G, respectively.

FIG. 2 shows absorption spectra of PbSe core, PbSe/PbS core-shell and PbSe/PbSeₓS₁₋ₓ core-alloyed shell semiconductor nanocrystals with various sizes and composition, covering various spectral regimes between 500-2500 nm, wherein the upper curve represents the solar energy radiation.

FIG. 3 shows a schematic drawing of a typical photovoltaic cell comprising closed-packed film of group IV-VI semiconductor core-shell nanocrystal quantum dots or nanorods as photoactive layer, sandwiched between collecting electrodes. In particular, the photovoltaic cell is fabricated on an indium tin oxide (ITO)-coated glass as the anode, on which electron and/or hole blocking layers (HBL) are optionally coated. An aluminum (Al) cathode is on top of the photo-active layer. The photoactive film can be prepared either by drop casting or a spray technique, as shown in the upper inset presenting an image of core-shell NQDs having diameter of 5 nm, or further treated by N₂/H₂ gas in order to reduce the inter-dot spacing thus improving a carrier diffusion, as shown in the lower inset presenting an image of core-shell NQDs having diameter of 3.5 nm.

FIG. 4 shows a schematic drawing of a fluorescence collector, comprising group IV-VI semiconductor nanocrystals (NQDs/NRs) sandwitched between a pair of Bragg reflectors, emitting at a wavelength suitable for pumping a photovoltaic cell (PVC) of a known configuration, including either group IV-VI core-sheel or core-alloyed shell semiconductor nanocrystals or nanorods, or alternatively, another infrared absorber, as photoactive components.

### DETAILED DESCRIPTION OF THE INVENTION

The present invention relates to a photovoltaic cell (PVC) comprising group IV-VI core-shell or core-alloyed shell semiconductor nanocrystals as photoactive components, as defined above.

In one embodiment, the photovoltaic cell of the present invention comprises group IV-VI semiconductor nanocrystals as photoactive components, wherein each one of said nanocrystals is a core-shell semiconductor nanocrystal comprising a core of a first group IV-VI semiconductor material having a selected band gap energy and a core-overcoating shell consisting of a second group IV-VI semiconductor material.

In another embodiment, the photovoltaic cell of the present invention comprises group IV-VI semiconductor nanocrystals as photoactive components, wherein each one of said nanocrystals is a core-alloyed shell semiconductor nanocrystal comprising a core of a first group IV-VI semiconductor material having a selected band gap energy and a core-overcoating alloyed shell consisting of an alloy of said first group IV-VI semiconductor material and a second group IV-VI semiconductor material.

The group IV-VI semiconductor core-shell and core-alloyed shell nanocrystals used according to the present invention are photoactive materials showing a broadband absorption with a cross section of σ_{gs}=10⁻¹⁴-10⁻¹⁵ cm². These nanocrystals can be prepared either by simple colloidal chemical procedures (Brumer et al., 2005, Yu et al., 2004; Harbold et al., 2005; Guyot-Sionnest and Wherenberg, 2005; Bakueva et al., 2003; Steckel et al., 2003; McDonald et al., 2004; Murray et al., 2001) or by thermospray or electrospray methods (Amirav et al., 2005; Amirav and Lifshitz, 2008), and exhibit distinct electronic states tunable with the variation of the nanocrystalline diameter.

In particular, the present invention relates to photovoltaic cells (PVCs) comprising group IV-VI semiconductor nanocrystals, showing a narrow band gap in the bulk (˜4 micron), which are tuned within the near infrared spectral regime (800-3500 nm) and have internal quantum efficiency greater than 20% and up to 80% (Brumer et al., 2005). These photoactive materials enable to harvest the energy from a wide range of the solar spectrum, more specifically, from the visible regime up to the bandgap energy in the infrared regime, showing a band-edge radiative lifetime of a sufficient duration, i.e., a few hundreds nanoseconds (Kigel et al., 2008; Kigel et al., 2008), and permitting efficient charge separation, wherein the photogenerated carriers exhibit small effective masses of the electrons and holes (m_{e,h}≈0.1 m₀), giving a superior transport properties.

As previously described (Schaller and Klimov, 2004; Ellingson et al., 2005; Allan and Delerue, 2004; Allan and Delerue, 2005), absorption of a photon in the ultraviolet and visible regime with E_{exc}=nE_{g} results in the generation of multiple excitons at E_{g} at low band gap semiconductor nanocrystal quantum dots, e.g., PbSe. This effect is known as the impact ionization process or an inverse process to an Auger recombination. In other words, harvesting of the infrared light leads to the creation of a single electron-hole pair, while harvesting of the ultraviolet/visible light leads to the creation of additional electron-hole pairs, avoiding the loss of the surplus energy as heat and enhancing the generation of excess charge carriers. Thus, absoption of the visible and infrared portions of the solar radiation may be efficiently utilized in a photovoltaic cell. Several theoretical evaluations predict that the impact ionization process may increase the energy conversion efficiency of a nanocrystal quantum dot (NQD)-based photovoltaic cell up to 43% (Klimov, 2006), although the efficiency of the impact ionization process is still debatable. Anyhow, these multiple carriers can repel each other in a simple direct band gap NQDs, unless they are spatially separated.

As stated hereinabove, the group IV-VI core-shell and core-alloyed shell semiconductor nanocrystals used in the photovoltaic cells of the present invention can be prepared by simple colloidal chemical procedures associated with the injection of precursors into a hot solution, with a final formation of nanocrystals with organic surface capping, as described in detail in the aforesaid WO 2006/027778 and in Example 1 hereinafter. These procedures are controllable and reproducible. The organic capping facilitates dispersion of these semiconductor nanocrystals in various media, spin casting them on various surfaces and removing them by heat, and can be exchanged for better adhesion, if necessary. Thus, the procedure allows chemical flexibility, cheap production and scalable processes.

The group IV-VI semiconductor nanocrystals used in the photovoltaic cells of the present invention can further be prepared by thermospray or electrospray methodologies, described in detail in the aforesaid WO 2006/035425 and in Example 2 hereinafter. Using these methodologies, nanocrystals are crystallized from micron size droplets, thermo- or electro- sprayed from a dilute salt solution, by evaporation of the solvent during a flow toward a target. Thus, surfactant-free nanocrystals are deposited onto a desired substrate, e.g, transparent conducting electrode or hole-transporting layer (HTL) (Amirav et al., 2005). Under appropriate conditions, plurality of core and core-(alloyed) shell with spherical or rod shapes may be formed and, in particular, when deposited as a thin film with a controlled thickness and nearly intimate contact between adjacent nanocrystals, permitting efficient charge diffusion (Amirav and Lifshitz, 2008). Surfactant-free nanocrystalline-based photovoltaic cells may require external encapsulation, avoiding oxidation of the photoactive layer.

In one embodiment, the group IV-VI semiconductor nanocrystals used in the photovoltaic cells of the present invention are thus in the form of spheroids, i.e., in the form of nanocrystal quantum dots (NQDs). As used herein, “a nanocrystal quantum dot” refers to an inorganic crystallite between about 2 nm and about 1000 nm in diameter, preferably between about 2 nm and about 50 nm, more preferably between about 2 nm to about 20 nm, that is either of a core-shell or a core-alloyed shell configuration as defined hereinabove.

In another embodiment, the group IV-VI semiconductor nanocrystals used in the photovoltaic cells of the present invention are in the form of rods, in which the overcoating shell is non-concentric with respect to the core, i.e., nanorods (NRs). As used herein, “a nanorod” refers to an inorganic crystallite of a core-shell or a core-alloyed shell configuration as defined hereinabove, in which the overcoating shell or alloyed shell is non-concentric with respect to the core, with a width of 2-20 nm, preferably 3-7 nm, and a length not longer and preferably close to the effective radius of an exciton, which is determined by the specific nanorod material, e.g., about 48 nm for PbSe. Such nanorods, when used in photovoltaic cells according to the present invention, permit efficient charge separation between the core and the overcoating shell, followed by competent charge extraction into collecting electrodes.

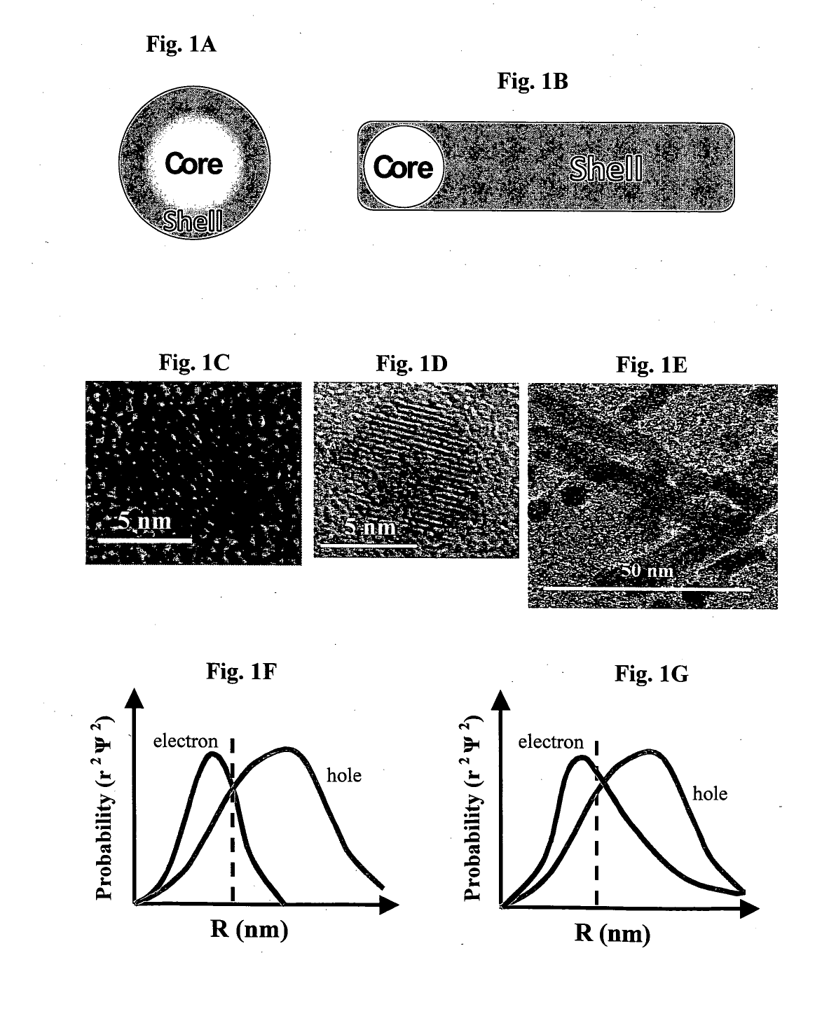

Thus, the present invention particularly relates to a photovoltaic cell comprising group IV-VI semiconductor core-shell or core-alloyed shell nanocrystals, either in the form of spheroids or nanorods, composed of a core of a first group IV-VI semiconductor material, e.g., PbSe, covered with an epitaxial layer consisting of either a second group IV-VI semiconductor material, e.g., PbS, or an alloy with gradual composition of said first and second group IV-VI semiconductor materials, e.g., an alloy having the structure of PbSeₓS₁₋ₓ (as described hereinafter). These nanocrystals may be concentric with a spheric symmetric shape, providing nanocrystal quantum dots (NQDs), or non-concentric with a rod shape, providing nanorods (NRs), as shown in FIG. 1. The core-shell and the core-alloyed shell nanocrystals show chemical robustness over months and years (Brumer et al., 2005) and special photo-stability. In addition, these nanocrystals show an internal staggered electronic configuration (Maria et al., 2005; Cui et al., 2006) when E_{C}(PbSe)>E_{C}(PbS)>E_{V}(PbSe)≧E_{V}(PbS), providing that E_{V} and E_{C} are the valence and conduction band energies, respectively, wherein the band offset between the core and the overcoating shell depends on the ratio between the core diameter and the shell thickness, which allows partial separation of the photogenerated electron and hole wavefunctions, reduction of the recombination process and improvement of charge separation, and plausibly enhances charge extraction, particularly in the non-concentric core-alloyed shell nanocrystals.

The atomic spacing of the overcoating alloyed shell should be close to that of the core material in order to prevent crystallographic mismatch that would result in the formation of carriers trapping sites. However, the gradual change of the alloyed shell atomic spacing should relax the stick demand and offer the ability to use a variety of semiconductors for the alloyed shell, including combinations of core/shell that have not been previously disclosed. The atomic spacing should be identical to that of the core material or different from that of the core material by up to 5%. The crystallographic structure should be identical to that of the core material.

While referring to both the core-shell and the core-alloyed shell nanocrystal configurations, both the core and the core-overcoating shell, if present, have the structure of AB or AC; and the core-overcoating alloyed shell, if present, consists of an alloy of the ABₓC₁₋ₓ structure, wherein A may be, for example, Pb; B and C each independently may be, for example, S, Se or Te; x is the mole fraction of B and 1−x is the mole fraction of C, with x gradually changing within a range wherein x<1 and x>0.

In one embodiment, the core semiconductor material has a band gap energy in the infrared range. In preferred embodiments, the core semiconductor material is PbS, PbSe or PbTe; the core-overcoating shell, if present, is made of PbS, PbSe or PbTe; and the core-overcoating alloyed shell, if present, has the PbSeₓS₁₋ₓ structure wherein x is the mole fraction of Se and 1−x is the mole fraction of S, with x gradually changing within a range wherein x<1 and x>0. In more preferred embodiments, the invention provides photovoltaic cells comprising group IV-VI semiconductor nanocrystals as photoactive components, wherein each one of said nanocrystals is (i) a core-shell semiconductor nanocrystal wherein the core semiconductor material is PbSe and the shell material is PbS; or (ii) a core-alloyed shell semiconductor nanocrystal wherein the core semiconductor material is PbSe and the alloyed shell material has the PbSeₓS₁₋ₓ structure as defined above.

In one embodiment, the alloyed shell of the semiconductor nanocrystals exhibits gradual change of the crystallographic lattice spacing from the crystallographic lattice spacing of the core to that of the most outer layer. The shell is a ternary alloy and as such its semiconducting and structural properties, such as the lattice parameter, the energy gap, etc., can be varied in a controlled fashion by varying the alloy composition. The composition of the alloy can be of a ternary alloy as defined above, i.e., ABₓC₁₋ₓ, with x gradually changing within a range wherein x<1 and x>0. Thus, for example, in the case of the alloyed shell PbSeₓS₁₋ₓ, the composition and hence the material properties will gradually change from those of PbSe to those of PbS. The composition change follows along the nanocrystal radius, R, where the alloyed shell composition is similar to that of the core for the lower values of R and x decreases towards its minimum value as R increases. The crystallographic lattice spacing gradual change prevents interface defects between the core and the shell. Such defects can serve as trap sites for charge carriers and damage the photovoltaic efficiency.

In another embodiment, the alloyed shell of the semiconductor nanocrystals exhibits gradual change of the dielectric constant, thus improving the internal quantum yield by decreasing carriers', i.e., electrons or holes', trapping probability in an abrupt core-shell interface.

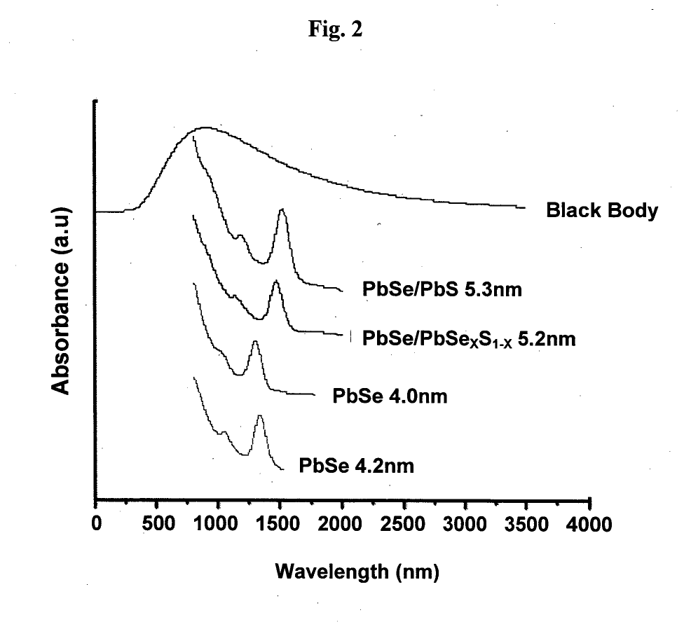

The size and the composition of the core-shell and core-alloyed shell semiconductor nanocrystals affect their characteristic spectral absorption wavelength, as further shown in FIG. 2, displaying the absorption spectra of a few samples of PbSe, PbSe/PbS and PbSe/PbSeₓS₁₋ₓ nanocrystals, covering the spectral regime between 500-2500 nm. In other words, for any particular composition selected for the semiconductor nanocrystals used in the photovoltaic cell of the present invention, it is possible to tune the absorption to a desired wavelength by either controlling the size of the particular composition of the semiconductor nanocrystals, preferably between 2 nm to 20 nm, or varying the composition of a fix size semiconductor nanocrystals.

Thus, in one embodiment, the group IV-VI semiconductor nanocrystals used in the photovoltaic cell of the present invention, whether core-shell or core-alloyed shell configuration nanocrystals, have a tunable single exiton absorption in the spectral range of 800-3500 nm.

In another embodiment, the size of these semiconductor nanocrystals used in the photovoltaic cell of the present invention is in the range of about 2 to about 50 nm, more preferably from about 2 nm to about 20 nm.

In a further embodiment, the group IV-VI semiconductor nanocrystals used in the photovoltaic cell of the present invention, whether core-shell or core-alloyed shell configuration nanocrystals, have an impact ionization process excited in the ultraviolet and visible spectral regime that leads to multiple carrier generation, thus enabling absorption processes that cover a wide spectral range.

As stated above, both core-shell and core-alloyed shell nanocrystals exhibit a special chemical stability over years and an internal staggered energy band alignment. As a consequence, this configuration enables an internal charge separation between the core and the shell, reducing the repulsion between multiple carriers generated by impact ionization process (Piryatinski et al., 2007).

Thus, in still a further embodiment, the semiconductor nanocrystals used in the photovoltaic cell of the present invention have an efficient internal charge separation.

As previously disclosed by the inventor of the present invention (Lifshitz et al., 2006), the group IV-VI semiconductor NQDs, either in their core or core-shell configuration, exhibit small effective masses of the electrons and holes (m_{e,h}=0.1 m₀), giving superior transport properties, and further show chemical robustness over years and special photo-stability. These specific properties overcome the problems known in plastic photovoltaic solar cells based on polymer photoactive materials and known to undergo a relatively fast photo-degradation. Thus, the group IV-VI semiconductor nanocrystal-based photovoltaic cell of the present invention has a benefit of the plastic photovoltaic technology with respect to the chemical- and photo-stability.

Furthermore, one of the known problems in plastic photovoltaic cells concerns the lose of photo-generated carriers due to the competing radiative recombination processes, since the carriers do not travel far enough (<10 nm) before electrons and holes find each other and recombine. One of the ways to overcome this problem is by the creation of a donor-acceptor (D-A) hetero-junction. In fact, the semiconductor nanocrystals used in the photovoltaic cell of the present invention behave like D-A pairs and are therefore being in an intimate contact and, as stated above, allow an immediate charge separation that is further enhanced by the electrode potentials. In a different configuration, a D-A bilayer hetero-junction can be mimicked using nanocrystal films with different electron affinities.

In preferred embodiments of the photovoltaic cell of the present invention, monodispersed nanocrystals are required, having systematic control of the optical properties, permitting closed packing of the nanocrystals into a photovoltaic film, permitting charge migration within said film, when a nanocrystal with a deviated size may act as a carrier's trap. As used herein, “monodispersed nanocrystals” means a colloidal system in which the suspended particles have substantially identical size and shape with standard deviations of less than a 5% root-mean-square deviation (RMSD) in diameter. Further narrowing of the sample monodispersity can be done by optical means, through selective excitation of only a fraction of the sample. The more preferable standard deviation of 5% corresponds to ± one lattice constant throughout the 1-15 nm size range.

In one embodiment, the group IV-VI semiconductor nanocrystals used in the photovoltaic cell of the present invention exhibit photoluminescence having quantum yields greater than 20%. In preferred embodiments, the quantum yields is greater than 40%, more preferably greater than 60%, most preferably about 80%. With this respect it should be noted that a photovoltaic cell requires efficient generation of electron-hole pairs and immediate charge separation, wherein an efficient recombination with a high quantum yields should be avoided. However, the measure of emission quantum yield reflects the existence of high quality nanocrystals free of carriers' traps. This will not be in contradiction to the photovoltaic cell, as long as the radiative lifetime is relatively long. For example, a single exciton lifetime in PbSe dots is close to a microsecond, leaving sufficient time for charge extraction, way before an efficient electron-hole recombination occurs.

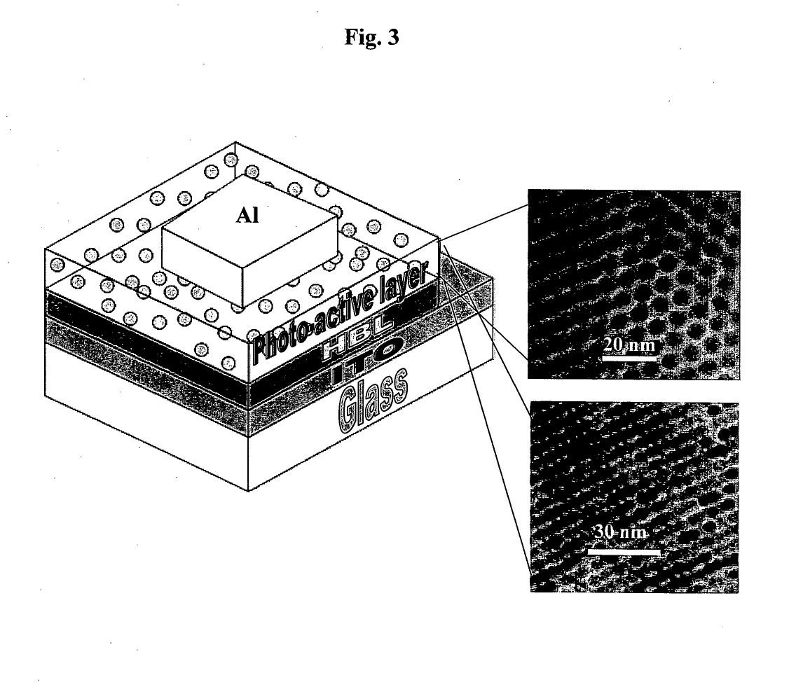

FIG. 3 shows a schematic drawing of a typical photovoltaic cell comprising closed-packed film of group IV-VI semiconductor core-shell nanocrystal quantum dots or nanorods as photoactive material, sandwiched between collecting electrodes. The photovoltaic cell is fabricated, e.g., on an indium tin oxide-coated glass as the anode, on which electron and/or hole blocking layers are optionally coated. A cathode, e.g., made of aluminum, is on top of the photo-active layer. The photoactive film, preferably with a thickness of 100-200 nm, can be prepared either by drop casting or a spray technique, or further treated by N₂/H₂ gas in order to reduce the inter-dot spacing thus improving a carrier diffusion. The device can be encapsulated by epoxy resin for further protection from the environment.

The photovoltaic cell of the present invention may be constructed in any of the various configurations known in the art, namely, the group IV-VI semiconductor nanocrystals, either in their core-shell or core-alloyed shell configuration, as the photoactive components, may be packed in any suitable configuration, enhancing either the photo-current or the photo-voltage and thus, the conversion efficiency.

In one possible configuration, the semiconductor nanocrystals are formed into thin film with inter-nanocrystalline spacing sufficiently small (<1 nm) to allow efficient charge diffusion (Artemyev et al., 1999; Artemyev et al., 2000; Micic et al., 2001). Thus, a small inter-nanocrystalline spacing may be achieved by either an exchange of the nanocrystals surfactants by short molecules, e.g., thioethaneamine or bidentate molecules, or partial thermal evaporation of the surfactants under forming gas (95% N₂ and 5% H₂), hydrogenating the nanocrystals' external surfaces (Brumer et al., 2006).

As mentioned above and shown schematically in FIG. 3, the separation of the photo-generated charges occurs at the PbSe/PbS core-shell interface, due to the specific staggered energy band alignment. According to this configuration, the hole resides at the E_{V}(PbS) state, while the electron, more likely is at the E_{C}(PbSe) state, depending on the relative dimensions of the core and the shell. Once the charge separation happens, the transport of the electrons and holes towards the collecting electrodes is symmetrical, due to the similarity of the carriers' effective masses. Thus, the PbSe/PbS interface enhances the diffusion driving force for charge extraction and reduces the chance for an exciton recombination.

Thus, in one embodiment, the photovoltaic cell of the present invention comprises group IV-VI semiconductor nanocrystals, as defined above, as photoactive components, wherein said nanocrystals are packed as a single layer thin film, sandwiched between collecting electrodes and acting as an insolating layer in a p-i-n configuration, wherein an efficient internal charge separation in each one of said nanocrystals allows the migration of a charge carrier to a relevant collecting electrode.

Previous studies performed during the recent years showed that photovoltaic effect can be achieved in systems consisting of nanocrystal quantum dots in conjunction with semiconductor polymer. The nanocrystal quantum dots/polymer pair can be packed as a hetero-junction configuration or forming a disordered blend (Cui et al., 2006; Sargent, 2005; Zhang et al., 2005; Alivisatos, 1996). Upon photo-excitation of the NQDs, holes are injected into the polymer component and are collected by the hole collecting electrode. The electrons remain in the NQDs, and are collected through diffusion and percolation among the nanocrystalline component toward the electron collecting electrode. However, the polymer based devices have a few drawbacks associated with the photo-degradation of the polymer themselves and their tendency for oxidation. On the other hand, preliminary examples (Gur et al., 2005; Zhong et al., 2007; Zhong et al., 2007) proposed an efficient charge separation, which occurs at the interface between two inorganic semiconductor nanocrystals, avoiding the involvement of an organic component.

Hence, in an additional possible configuration, the semiconductor nanocrystals are formed into a bi-layer hetero-juction array of nanocrystals, e.g., PbSe—PbS core-shell nanocrystals. In particular, the first PbSe array is formed by spin casting it onto the ITO(+buffer) substrate and annealing it for a period of time. Once the first layer is stable, a subsequent deposition of the second NQDs array is allowed. These bi-layer hetero-junction arrays should supply a system with a staggered energy configuration, as shown schematically in FIG. 3, wherein upon photo-excitation, holes find the lowest valence states on one layer, while the electrons reside at the lowest conduction states of the second layer. In other words, the charge extraction is driven by directed diffusion, as dictated in donor-acceptor (D-A) hetero-junctions. Once the charges are separated, the majority carriers readily diffuse into the relevant electrodes and are blocked from moving through the whole layer into the opposite electrode.

Thus, in another embodiment, the photovoltaic cell of the present invention comprises group IV-VI semiconductor nanocrystals as defined above, as photoactive components, wherein said nanocrystals are packed as a bi-layer hetero-junction comprising a layer of nanocrystals in conjunction with either a second layer of nanocrystals or a conductive polymer film having a staggered energy band alignment that facilitate a charge transfer of a donor-acceptor pair, which is sandwiched between collecting electrodes.

In a further embodiment, the photovoltaic cell of the present invention comprises group IV-VI semiconductor nanocrystals as defined above, as photoactive components, wherein said nanocrystals are packed as a single layer of a nanocrystal-conductive polymer blend having a staggered energy band alignment that facilitates a charge transfer of a donor-acceptor (D-A) pair, which is sandwiched between collecting electrodes and permits an excess charge separation and a charge carrier diffusion to a relevant collecting electrode.

The conductive polymer for use in the present invention may be any suitable conductive polymer such as, without being limited to, poly(acetylene)s, poly(pyrrole)s, poly(thiophene)s, poly(aniline)s, poly(fluorene)s, poly(3-alkylthiophene)s, polytetrathiafulvalenes, polynaphthalenes, poly(p-phenylene sulfide) and poly(para-phenylene vinylene)s. In preferred embodiments, the conductive polymer is poly[2-methoxy-5-(2′-ethyl-hexyloxy)-1,4-phenylene vynylene] (MEH-PPV) or poly-3-hexylthiophene (P3HT).

An additional possible configuration of the photovoltaic cell of the present invention is based on dye-sensitization of nanocrystalline TiO₂ layers (Bach et al., 1998; Gratzel, 2007; Plass et al., 2002). In a dye-sensitized solar cell (DSSC), dye molecules are chemisorbed onto a surface of 10-30 nm size TiO₂ particles that have been sintered into a highly porous micron TiO₂ film wherein, upon photo-excitation of said dye molecules, electrons are injected from the dye into the conduction band of the TiO₂, affecting the charge separation and the production of a photovoltaic effect. As proposed herein, group IV-VI semiconductor nanocrystals can be adsorbed from colloidal solution on the TiO₂ (Zaban et al., 1998; Vogel and Weller, 1994), instead of dye molecules. Such a configuration may be even more efficient in view of the nanocrystals' tunability of the optical properties with size, chemical- and photo-stability.

Thus, in still a further embodiment, the photovoltaic cell of the present invention comprises group IV-VI semiconductor nanocrystals as defined above, as photoactive components, wherein said nanocrystals are packed as a single layer of nanocrystals deposited onto a TiO₂ (titania) particle film and act as photo-sensitizers, injecting their electrons into the TiO₂ film.

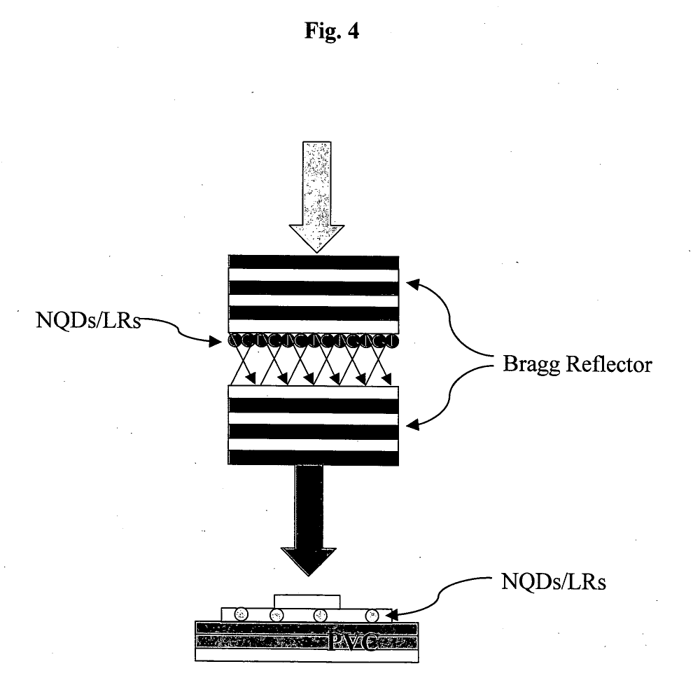

In still an additional possible configuration, the group IV-VI semiconductor nanocrystals may be packed between a pair of Bragg reflectors, creating a photonic structure, which acts as a fluorescence collector harvesting a wide spectral range of the solar radiation. In particular, the photons emited by the nanocrystals at their band-edge energy are internally reflected within a photonic cavity and then emitted from said photonic cavity with an enhanced intensity. The fluorescence collector is coupled to a common photovoltaic cell, such as a Si-based photovoltaic cell, as previously described (Rau et al., 2005; Swift and Smith, 2003; Gallgher et al., 2007), or to a photovoltaic cell according to the present invention, wherein the photons emitted from the photonic cavity are tuned to the absorption edge of the photoactive material being a component of said photovoltaic cell, as schematically illustrated in FIG. 4.

Thus, in another aspect, the present invention provides a photovoltaic device comprising a photovoltaic cell and a photonic structure that acts as a fluorescence collector, harvesting a wide spectral range of solar radiation, comprising group IV-VI semiconductor nanocrystals as photoactive components, packed as a single layer between a pair of Bragg reflectors,

wherein said nanocrystals are either:
(i) core-shell semiconductor nanocrystals each comprising a core of a group IV-VI semiconductor material having a selected band gap energy and a core-overcoating shell consisting of a second group IV-VI semiconductor material; or
(ii) core-alloyed shell semiconductor nanocrystals each comprising a core of a group IV-VI semiconductor material having a selected band gap energy and a core-overcoating alloyed shell consisting of an alloy of said group IV-VI semiconductor material and a second group IV-VI semiconductor material,

said nanocrystals emit photons at their band-edge energy, and said photons are internally reflected within a photonic cavity and then emitted from said photonic cavity with an enhanced intensity tuned to the absorption edge of a photoactive material being a component of said photovoltaic cell.

The group IV-VI semiconductor nanocrystals used in the photonic structure of the photovoltaic device of the present invention may be in the form of spheroids or rods, i.e., either quantum dots or nanorods, and of any of the configurations and properties defined above.

The invention will now be illustrated by the following non-limiting Examples.

### Examples

### Example 1

### Preparation of PbSe/PbS Core-Shell and PbSe/PbSe₁₋ₓSₓ Core-Alloy-Shell Nanocrystal Quantum Dots (NQDs) and a Corresponding Closed Packed Film

PbSe and PbS were synthesized in a three-neck flask equipped with a condenser, a magnetic stirrer, a thermocouple and a heating mantle. The Pb precursor solution is prepared by mixing PbO [or Pb(acetate)₂], oleic acid (OA) and technological grade 1-octadecene (ODE) [or phenyl-ether], heating the mixture to 150° C. until the solution becomes colourless, and further heating the mixture to 180° C. The Se (or S) precursor solution was prepared by mixing selenium or sulphur with trioctylphosphine (TOP), followed by a quick injection of this solution into the hot Pb precursor solution. The temperature of the final solution was then dropped to 150° C. All steps in the reactions were carried out under argon (Lifshitz et al., 2006). The corresponding CdSe and CdTe compounds are prepared in a similar manner, using CdO as the starting precursor, dissolved in OA and ODE solution. The CdX NQDs compounds are grown at 260° C. (Kloper et al., 2007).

For the PbSe/PbS core-shell nanocrystal quantum dots (NQDs)' preparation, PbSe cores were initially prepared and then coated by PbS shells, by means of a second injection of the stoichiometric amounts of PbO and TOP:S precursor solutions into the reaction solution. PbSe/PbSe₁₋ₓSₓ core-alloy-shell NQDs were produced by simultaneous injections of Pb, Se and S precursors, Pb(acetate)₂, TOP:Se and TOP:S, into a phenyl-ether mother solution. The composition of the core-shell structures was determined by drawing of intermediate aliquots from the reaction solution during the NQDs' growth and their examination by energy dispersive analysis of X-ray diffraction (EDAX). Preliminary EDAX measurements of representative samples revealed the creation of embryonic PbSe nuclei and a delayed precipitation of PbSe₁₋ₓSₓ shell on the PbSe core surfaces, which led to the formation of air stable PbSe/PbSe₁₋ₓSₓ core-alloy-shell NQDs, and PL QE of 80% (Brumer et al., 2005; Lifshitz et al., 2006; Solomeshch et al., 2006). The morphology and crystallography of the colloidal NQDs was examined by transmission electron microscopy (TEM), high-resolution TEM (HR-TEM) and selected-area-electron-diffraction (SAED).

FIG. 1A shows a schematic drawing of a core-shell NQD, when an alloy layer is optionally exist between the core and the shell as demonstrated by the shaded area; FIGS. 1C-1D show representative transmission electron microscope images of core-shell NQDs having either core diameter of 3.9 nm and shell thickness of 0.55 nm, or core diameter of 1.8 nm and shell thickness of 1.6 nm, respectively; and FIG. 1F shows the plausible electron-hole wave function radial distribution of a core-shell NQD.

Closed-packed films of the aforesaid NQDs were formed by drop casting onto a surface, e.g., collecting electrode or carriers' collecting layer. These closed-packed film can further be annealed under forming gas, minimizing the inter-QD spacing, as shown in FIG. 3 (lower inset). Alternatively, a closed-packed film can be formed by a spray methodology as described in WO 2006/035425.

### Example 2

### Preparation of PbSe/PbS Core-Shell Nanocrystal Rods (NRs)

PbSe/PbS core-shell nanocrystal rods (NRs) are be formed by a few steps procedure, starting with the synthesis of PbSe cores, described in detail in Example 1 hereinabove. The second step may involve the preparation of the first shell, by a fast injection of a precursors' solution into the cores' mother solution at 180° C., wherein, the precursor solution composed of 0.2 gr of lead acetate and 0.192 gr of sulfur dissolved in 2 ml of tri-octyl-phosphine. Following the injection, the temperature of the mother solution is dropped to 110° C. and the growth of the first shell is continued for about 50 min. The third step may repeat the procedure described herein for the second step, adding further precursor solution by a fast injection and continuing the growth for about additional 40 min. The fourth and fifth steps may repeat again the procedures described hereinabove for the previous shell growth. The consecutive injections can lead to an in homogenous growth, over a certain facet beyond the first shell (Bashouti and Lifshitz, 2008), forming non-concentric PbSe/PbS core-shell structures.

FIG. 1B shows a schematic drawing of a core-shell NR; FIG. 1E shows a representative transmission electron microscope image of core-shell NRs with length of ˜50 nm and width of ˜3 nm; and FIG. 1G shows the plausible electron-hole wave function radial distribution of a core-shell NR.

### Example 3

### Preparation of CdTe/CdSe Core-Shell NQDs

The synthesis of core CdTe spherical nanocrystals was based on a colloidal procedure, involving the injection of precursors into a mother solution at relatively elevated temperatures. For that purpose, a few solutions were prepared under standard inert conditions: (i) A Te-precursor solution was prepared by dissolving 0.0128 gr of Te (0.1 mmol) in 0.11 ml of trioctylephosphine (TOP) until the solution attained a clear yellowish colour. The solution was further diluted with octadecene (ODE) to a total volume of 1 ml. (ii) A Cd-precursor solution was prepared by mixing 0.0256 gr of CdO with 300 μl oleic acid in 10 ml ODE solution. The obtained solution was heated to 100° C. for 30 minutes under vacuum in a three-neck flask to remove the water content, creating a homogeneous red solution that was then flushed by dry Ar gas, while raising the temperature to 300° C., and became transparent upon the generation of cadium oleate (Cd(OA)₂). A crucial additional stage was done by further heating the Cd-precursor solution up to 310° C., for a duration of about 30 minutes, leading to the formation of a gray precipitate, which was undoubtedly characterized as crystalline Cd⁰ nanoparticles.

The TOP:Te precursor solution was injected into the three-neck flask about 30 seconds after the first appearance of the Cd⁰ precipitate, initiating the nucleation of the core CdTe nanocrystals, followed by an immediate drop of the temperature to 260° C., where further growth of the CdTe nanocrystals took place. The growth of the nanocrystals occurred during the first 1-5 minutes while the color of the solution was gradually changing from yellow to red. The growth of the core CdTe nanocrystals was stopped by cooling the solution to 210-240° C.

A systematic study (Kloper et al., 2007) revealed that both the Cd⁰ and the Cd(OA)₂ molecules acted as a reservoir of Cd monomers in the reaction. Although under similar conditions, there is a tendency for the formation of CdTe tetra-pods structure instead of spherical particles due to a rapid growth over reactive (111) facets at 300° C., this tendency is abolished in our case due to a slow supply of Cd monomers, restrained by the occurrence of continuous Cd⁰⇄Cd⁺² (solution) equilibrium during the nanocrystals' growth. The extra chemical equilibrium moderates the speed of the reaction over a reactive facet, enduring the growth of spherical nanocrystals with exceptionally high crystallinity and emission quantum efficiency.

The CdTe/CdSe core-shell nanocrystals preparation was based on the use of the pre-generated CdTe cores, followed by a second injection of the shell precursors, using two alternative methods. The first method involved initial filtration of the Cd⁰ nanoparticles away from the nanocrystals solution. This stage was followed by precipitation, upon the addition of methanol/acetone mixer, and centrifugation of the solid CdTe nanocrystals from the reaction solution. The creation of the core-shell structures then, required to re-dissolve the cores in a new Te-free solution. Alternatively, the CdTe core nanocrystals were utilized inside their original mother solution, after reducing the solution temperature to less than 240° C. Control experiments including transmission electron microscopy and absorption spectroscopy confirmed retention of the core nanocrystals size for an extended period of time at a final temperature ≦240° C. Thus, the shell precursors could have been injected directly into the original solution. This alternative permitted the production of high quality CdTe/CdSe core-shell structures, avoiding extra synthetic procedures, which reduced the quality of the core surfaces and consequently the overall quality of the core-shell nanocrystals.

A shell stock-solution was prepared by mixing the Cd-precursor described above with a Se-precursor solution, prepared by mixing 0.0517 gr Se and 0.11 ml of TOP, at room temperature. The room temperature shell stock-solution was injected into core CdTe nanocrystals solution at 210-240° C., causing a fall of the temperature to 170° C., and the reaction flask was then re-heated to 195-210° C. At this temperature, neither pure CdSe nor CdTe nanocrystals could be created, and a shell growth over the pre-generated CdTe core takes place instead. Eventually, the CdTe nanocrystals cores and CdTe/CdSe core-shell nanocrystals were isolated as a clean powder, or re-dissolved in a pure solvent, e.g., hexane. The creation of the CdSe shell was confirmed by growth of the nanocrystals diameter with respect to that of the core, as measured by transmission electron microscopy; stoichiometric determination of the atomic constituents, as measured by energy dispersive analysis of X-ray; and an absorption red-shift of the low exciton band, with respect to that of the core. In addition, the Raman spectra of the CdTe/CdSe showed a characteristic LO and TA frequencies associated with the existence of CdTe as well as CdSe constituents.

### References

Alivisatos A. P., J. Phys. Chem., 1996, 100, 13226-13239

Allan G., Delerue C., Phys. Rev. B, 2004, 70, 24532

Allan G., Delerue C., Mat. Sci. Eng. C, 2005, 25, 687

Amirav L., Amirav A., Lifshitz E., J. Phys. Chem. B, 2005, 109, 9857

Amirav L., Lifshitz E., J. Phys. Chem. C, 2008, 112, 13105

Artemyev M. V., Bibik A. I., Gurinovich L. I., Gaponenko S. V., Woggon U., Phys. Rev. B, 1999, 60, 1504

Artemyev M. V., Woggon U., Jaschinski H., Gurinovich L. I., Gaponenko S. V., J. Phys. Chem. B, 2000, 104, 11617

Bach U., Lupo D., Comte P., Moser J. E., Weissortel F., Salbeck J., Spreitzer H., Gratzel M., Nature, 1998, 395, 583

Bakueva L., Musikhin S., Hines M. A., Chang T. W. F., Tzolov M., Scholes G. D., Sargent E. H., Appl. Phys. Lett., 2003, 82, 2895-2897

Bashouti M., Lifshitz E., Inorganic Chemistry, 2008, 47, 678-682

Brabec C. J., Sariciftci N. S., Hummelen J. C., Adv. Funct. Mater., 2001, 11, 15

Brumer M., Kigel A., Amirav L., Sashchiuk A., Solomesch O., Tessler N., Adv. Fun. Mater., 2005, 15(7), 1111-1116

Brumer M., Sirota M., Kigel A., Sashchiuk A., Galun E., Burshtein Z., Lifshitz E., J. Appl. Opt., 2006, 45, 7488

Coakley K. M., Mcgehee M. D., Appl. Phys. Lett., 2003, 83, 3380

Cui D., Xu J., Zhu T., Paradee G., Ashok A., Appl. Phys. Lett., 2006, 88, 183111

Durisch W., Lam K-H., Close J., Appl. Energy, 2006, 83(12), 1339-1350

Ellingson R. J., Beard M. C., Johnson J. C., Yu P., Micic O. I., Nozik A. J., Shabaev A., Efros A. L., Nano Lett., 2005, 5, 865

Fujiwara H., Kondo M., Appl. Phys. Lett., 2007, 90, 013503

Gallagher S. J., Norton B., Eames P. C., Solar Energy, 2007, 81, 813-821

Gratzel M., Philosophhical Transactions of the Royal Society, A: Mathematical Physical& engineering Sciences, 2007, 365 (1853), 993

Günes S., Fritz K. P., Neugebauer H., Sariciftci N. S., Kumar S., Scholes G. D., Solar Energy Materials and Solare Cells, 2007, 91, 420

Gur I., Fromer N. A., Geier M. L., Alivisatos A. P., Science, 2005, 310, 462

Guyot-Sionnest P., Wherenberg B. D., J. Chem. Phys., 2005, 123, 074709

Halls J. J. M., Walsh C. A., Greenham N. C., Marseglia E. A., Friend R. H., Moratti S. C., Holmes A. B., Nature 1995, 376, 498-500

Hannappel T., Seidel U., Schimpe H. J., Kollomitsen Z., Moller K., Schwarzburg V., J. Cryst. Growth, 2007, 298, 777

Harbold J. M., Du H., Chen C., Krauss T. D., Cho K., Murray C., Krishnan R., Wise F. W., Phys. Rev. B, 2005, 72, 195312

Huynh W. U., Dittmer J. J., Alivisatos A. P., Science, 2002, 295, 2425

Kigel A., Brumer M., Miakov G., Sashchuik A., Lifshitz E., SMALL, 2008, in process

Klimov V. I., Appl. Phys. Lett., 2006, 89, 123118

Kloper V., Osovsky R., Kolny-Olesiak J., Sashchiuk A., Lifshitz E., J. Phys. Chem. C, 2007, 111, 10336

Koleilat G. I., Levina L., Shukla H., Myrskog S. H., Hinds S., Pattantyus-Abraham A. G., Sargent E. J., ACSNANO, 2008, 2, 833

Law M., Beard M.c., C. S., Luther J. M., Hanna M.c. and Nozik A. J., Nano Letters, 2008, 8, 3905

Lifshitz E., Brumer M., Kigel A., Sashchiuk A., Bashouti M., Sirota M., Galun E., Burshtein Z., Le Quang A. Q., Ledoux-Rak I., Zyss J., J. Phys. Chem. B, 2006, 110(50), 25356

Maria A., Cyr P., Klem E., Levina L., Sargent E. H., Appl. Phys. Lett., 2005, 87, 213112

McDonald S. A., Cyr P. W., Levina L., Sargent E. H., Appl. Phys. Lett., 2004, 85, 2089

Micic O. I., Ahrenkiel S. P., Nozik A. J., Appl. Phys. Lett., 2001, 78, 4022

Murray C. B., Shouheng S., Gaschler W., Doyle H., Betley T. A., Kagan C. R., IBMJ Res. & Dev., 2001, 45, 47

Nozik A. J., Physica E, 2002, 14, 115

Piryatinski A., Ivanov S., Tretiak S., Klimov V.I., Nano Lett., 2007, 7(1), 108

Plass R., Pelet S., Krueger J., Grätzel M., J. Phys. Chem. B, 2002, 106, 7578

Rau U., Einsele F., Glaeser G. C., Appl. Phys. Lett., 2005, 87, 171101

Sargent E. H., Adv. Mat., 2005, 17, 515

Schaller R. D., Klimov V. I., Phys. Rev. Lett., 2004, 92, 186601

Shockley W., Queisser H. J., J. Appl. Phys., 1961, 32, 510

Solomeshch O., Kigel A., Brumer M., Sashchiuk A., Medvedev V., Aharoni A., Razin A., Eichen Y., Banin U., Lifshitz E., Tessler N., J. App. Phys., 2006, 99, 079901

Steckel J. S., Coe-Sullivan S., Vulovic V., Bawendi M., Adv. Mater., 2003, 15, 1862

Swift P. D., Smith G. V., Applied Optics, 2003, 42, 5112

Vogel R., Weller H., J. Phys. Chem., 1994, 98, 3183

Yu G., Gao J., Hummelen J. C., Wudi F., Heeger A. J., Science, 1995, 270, 1789

Yu W. W., Falkner J. C., Shih B. S., Colvin V. L., Chem. Mater., 2004, 16, 3318

Zaban A., Micic O. I., Gregg B. A., Nozik A. J., Langmuir, 1998, 14, 3153

Zhang S., Cyr P. W., Mcdonald B. A., Sargent E. H., Appl. Phys. Lett., 2005, 87, 233101

Zhong H., Zhou Y., Yang Y., Yang C., Li Y., J. Phys. Chem. C, 2007, 111, 6538-6543

1. A photovoltaic cell comprising group IV-VI semiconductor nanocrystals as photoactive components, wherein said nanocrystals are either:
(i) core-shell semiconductor nanocrystals each comprising a core of a first group IV-VI semiconductor material having a selected band gap energy and a core-overcoating shell consisting of a second group IV-VI semiconductor material; or
(ii) core-alloyed shell semiconductor nanocrystals each comprising a core of a first group IV-VI semiconductor material having a selected band gap energy and a core-overcoating alloyed shell consisting of an alloy of said first group IV-VI semiconductor material and a second group IV-VI semiconductor material.

2. The photovoltaic cell of claim 1, wherein said nanocrystals are core-shell semiconductor nanocrystals.

3. The photovoltaic cell of claim 1, wherein said nanocrystals are core-alloyed shell semiconductor nanocrystals.

4. The photovoltaic cell of claim 1, wherein said nanocrystals are in the form of spheroids or rods.

5. The photovoltaic cell of claim 1, wherein the core and the core-overcoating shell, if present, each independently has the structure of AB or AC; and the core-overcoating alloyed shell, if present, consists of an alloy of the ABₓC₁₋ₓ structure, wherein A is Pb; B and C each independently is S, Se or Te; x is the mole fraction of 13 and 1−x is the mole fraction of C, with x gradually changing within a range wherein x<1 and x>0.

6. The photovoltaic cell of claim 1, wherein the band gap energy of said core semiconductor material is in the infrared range.

7. The photovoltaic cell of claim 6, wherein said core semiconductor material is PbS, PbSe or PbTe; said core-overcoating shell, if present, is made of PbS, PbSe or PbTe; and said core-overcoating alloyed shell, if present, has the PbSeₓS₁₋ₓ structure wherein x is the mole fraction of Se and 1−x is the mole fraction of S, with x gradually changing within a range wherein x<1 and x>0.

8. The photovoltaic cell of claim 7, wherein (i) said nanocrystals are core-shell semiconductor nanocrystals, the core semiconductor material is PbSe, and the core-overcoating shell is made of PbS; or (ii) said nanocrystals are core-alloyed shell semiconductor nanocrystals, the core semiconductor material is PbSe, and the core-overcoating alloyed shell has the PbSeₓS₁₋ₓ structure wherein x is the mole fraction of Se and 1-x is the mole fraction of S, with x gradually changing within a range wherein x<1 and x>0.

9. The photovoltaic cell of claim 1, wherein each one of said nanocrystals is a core-alloyed shell semiconductor nanocrystal, and said alloyed shell exhibits gradual change of the crystallographic lattice spacing and/or gradual change of the dielectric constant.

10. The photovoltaic cell of claim 1, wherein said group IV-VI semiconductor nanocrystals have (i) a tunable single exiton absorption in the spectral range of 800-3500 nm; (ii) an impact ionization process excited in the ultraviolet and visible spectral regime that leads to multiple carrier generation, thus enabling absorption processes that cover a wide spectral range; or (iii) an efficient internal charge carrier separation.

11. The photovoltaic cell of claim 1, wherein (i) said nanocrystals have a size in a range of about 2 nm to about 50 nm; (ii) said nanocrystals exhibit less than a 5% root-mean-square deviation (RMSD) in diameter; or (iii) said nanocrystals exhibit photoluminescence having quantum yields greater than 20%.

12. (canceled)

13. (canceled)

14. (canceled)

15. (canceled)

16. The photovoltaic cell of claims 1, wherein said nanocrystals are packed as:
(i) a single layer thin film, sandwiched between collecting electrodes and acting as an insolating layer in a p-i-n configuration, wherein an efficient internal charge separation in each one of said nanocrystals allows the migration of a charge carrier to a relevant collecting electrode;
(ii) a bi-layer hetero-junction comprising a layer of nanocrystals in conjunction with either a second layer of nanocrystals or a conductive polymer film having a staggered energy band alignment that facilitate a charge transfer of a donor-acceptor pair, which is sandwiched between collecting electrodes;
(iii) a single layer of a nanocrystal-conductive polymer blend having a staggered energy band alignment that facilitates a charge transfer of a donor-acceptor (D-A) pair, which is sandwiched between collecting electrodes and permits an excess charge separation and a charge carrier diffusion to a relevant collecting electrode; or
(iv) a single layer of nanocrystals deposited onto a TiO₂ particle film and act as photo-sensitizers, injecting their electrons into the TiO₂ film.

17. (canceled)

18. (canceled)

19. The photovoltaic cell of claim 16, wherein said conductive polymer is poly[2-methoxy-5-(2′-ethyl-hexyloxy)-1,4-phenylene vynylene] (MEH-PPV) or poly-3-hexylthiophene (P3HT).

20. (canceled)

21. A photovoltaic device comprising a photovoltaic cell and a photonic structure that acts as a fluorescence collector, harvesting a wide spectral range of solar radiation, comprising group IV-VI semiconductor nanocrystals as photoactive components, packed as a single layer between a pair of Bragg reflectors,
wherein said nanocrystals are either:
(i) core-shell semiconductor nanocrystals each comprising a core of a group IV-VI semiconductor material having a selected band gap energy and a core-overcoating shell consisting of a second group IV-VI semiconductor material; or
(ii) core-alloyed shell semiconductor nanocrystals each comprising a core of a group IV-VI semiconductor material having a selected band gap energy and a core-overcoating alloyed shell consisting of an alloy of said group IV-VI semiconductor material and a second group IV-VI semiconductor material,
said nanocrystals emit photons at their band-edge energy, and said photons are internally reflected within a photonic cavity and then emitted from said photonic cavity with an enhanced intensity tuned to the absorption edge of a photoactive material being a component of said photovoltaic cell.

22. The photovoltaic device of claim 21, wherein said nanocrystals are core-shell semiconductor nanocrystals.

23. The photovoltaic device of claim 21, wherein said nanocrystals are corealloyed shell semiconductor nanocrystals.

24. The photovoltaic device of claim 21, wherein said nanocrystals are in the form of spheroids or rods.

25. The photovoltaic cell of claim 7, wherein said core semiconductor material is PbSe; said core-overcoating shell, if present, is made of PbS; and said core-overcoating alloyed shell, if present, has the PbSeₓS₁₋ₓ structure wherein x is the mole fraction of Se and 1−x is the mole fraction of S, with x gradually changing within a range wherein x<1 and x>0.

26. The photovoltaic cell of claim 11, wherein (i) said nanocrystals have a size in a range of about 2 nm to about 20 nm; or (ii) said nanocrystals exhibit photoluminescence having quantum yields greater than 40%.
